(19) United States
(12) Patent Application Publication
(10) Pub. No.: US 2024/0429270 A1
(43) Pub. Date: Dec. 26, 2024

(54) METAL INSULATOR METAL CAPACITOR (MIM CAPACITOR)

(71) Applicant: INTERNATIONAL BUSINESS MACHINES CORPORATION, ARMONK, NY (US)

(72) Inventors: HUIMEI ZHOU, Albany, NY (US); Shahrukh Khan, Sandy Hook, CT (US); Baozhen Li, South Burlington, VT (US); Ruilong Xie, Niskayuna, NY (US); Yoo-Mi Lee, Montvale, NJ (US); Chih-Chao Yang, Glenmont, NY (US)

(21) Appl. No.: 18/340,052

(22) Filed: Jun. 23, 2023

(51) Int. Cl. H01G 4/005; H01L 29/06; H01L 29/423; H01L 29/66; H01L 29/775; H01L 29/786

(52) U.S. Cl. CPC H01L 28/90; H01L 29/0673; H01L 29/42392; H01L 29/66439; H01L 29/775; H01L 29/78696

(57) ABSTRACT

A metal insulator metal capacitor (MIM capacitor) between adjacent stacked nanosheet FETs, each include a first nanosheet stack including alternating layers of a first work function metal and a semiconductor channel material vertically aligned and stacked one on top of another and a second nanosheet stack including alternating layers of a second work function metal and the semiconductor channel material vertically aligned and stacked one on top of another, the second nanosheet stack on the first nanosheet stack. Forming adjacent stacked nanosheet FETs, each include a first nanosheet stack and a second nanosheet stack, the second nanosheet stack on the first nanosheet stack, and forming a MIM capacitor between adjacent stacked nanosheet field effect transistors.

### BACKGROUND

The present invention relates, generally, to the field of semiconductor manufacturing, and more particularly to a metal-insulator-metal (MIM) capacitor.

MIM capacitors are a key element for integration of system-on-chips, improving both circuit performance and down-scaling capability. A typical MIM capacitor includes a top metal electrode, a dielectric/insulator layer and a bottom metal electrode. Voltage is applied across the metal electrodes which results in charge storage within the formed capacitor configuration. MIM capacitors are used in functional circuits such as mixed signal circuits, analog circuits, radio frequency (RF) circuits, dynamic random access memory (DRAM), embedded DRAM, and logic operation circuits.

The MIM capacitor is usually embedded into upper back-end-of-the-line (BEOL) layers. Traditional methods of fabricating a MIM capacitor include stacking of multiple MIM capacitor layers that involve numerous lithography and etching steps. Some MIM capacitor designs, require many extra processing steps that may not be easily integrable into a conventional BEOL process. A complexity of current MIM capacitor fabrication methods can cause problems during the semiconductor manufacturing process that can hinder capacitance density increase and yield improvement.

### SUMMARY

According to an embodiment of the present invention, a semiconductor device is provided. The semiconductor device including a metal insulator metal capacitor (MIM capacitor) between adjacent stacked nanosheet field effect transistors.

According to an embodiment of the present invention, a semiconductor device is provided. The semiconductor device including a metal insulator metal capacitor (MIM capacitor) between adjacent stacked nanosheet field effect transistors, where the adjacent stacked nanosheet field effect transistors each include a first nanosheet stack on a substrate including alternating layers of a first work function metal and a semiconductor channel material vertically aligned and stacked one on top of another and a second nanosheet stack including alternating layers of a second work function metal and the semiconductor channel material vertically aligned and stacked one on top of another, the second nanosheet stack vertically aligned and stacked on top of the first nanosheet stack.

According to an embodiment of the present invention, a method is provided. The method including forming adjacent stacked nanosheet field effect transistors, where each adjacent stacked nanosheet field effect transistor includes a first nanosheet stack on a substrate including alternating layers of a first work function metal and a semiconductor channel material vertically aligned and stacked one on top of another and a second nanosheet stack including alternating layers of a second work function metal and the semiconductor channel material vertically aligned and stacked one on top of another, the second nanosheet stack vertically aligned and stacked on top of the first nanosheet stack, and forming a metal insulator metal capacitor (MIM capacitor) between adjacent stacked nanosheet field effect transistors.

### BRIEF DESCRIPTION OF THE DRAWINGS

The following detailed description, given by way of example and not intended to limit the invention solely thereto, will best be appreciated in conjunction with the accompanying drawings, in which:

FIG. 1 illustrates a top view of a semiconductor structure at an intermediate stage of fabrication, according to an exemplary embodiment;

FIGS. 2 and 3 each illustrate a cross-sectional view of the semiconductor structure of FIG. 1 along section lines Y1-Y1 and Y2-Y2, respectively, FIGS. 2 and 3 are parallel to each other, according to an exemplary embodiment;

FIGS. 4 and 5 each illustrates a cross-sectional view of the semiconductor structure along section lines Y1-Y1 and Y2-Y2, respectively, and illustrates formation of an opening and a liner in the opening, according to an exemplary embodiment;

FIGS. 6 and 7 each illustrates a cross-sectional view of the semiconductor structure along section lines Y1-Y1 and Y2-Y2, respectively, and illustrates formation of an outer plate, an insulator and an inner plate, according to an exemplary embodiment;

FIGS. 8 and 9 each illustrates a cross-sectional view of the semiconductor structure along section lines Y1-Y1 and Y2-Y2, respectively, and illustrates removal of portions of the outer plate, the insulator and the inner plate, according to an exemplary embodiment;

FIGS. 10 and 11 each illustrates a cross-sectional view of the semiconductor structure along section lines Y1-Y1 and Y2-Y2, respectively, and illustrates formation of a dielectric, according to an exemplary embodiment;

FIGS. 12 and 13 each illustrates a cross-sectional view of the semiconductor structure along section lines Y1-Y1 and Y2-Y2, respectively, and illustrates formation of an inner plate metal, according to an exemplary embodiment;

FIGS. 14 and 15 each illustrates a cross-sectional view of the semiconductor structure along section lines Y1-Y1 and Y2-Y2, respectively, and illustrates formation of an inter-layer dielectric, a via and an Mx metal line, according to an exemplary embodiment;

FIGS. 16 and 17 each illustrates a cross-sectional view of the semiconductor structure along section lines Y1-Y1 and Y2-Y2, respectively, and illustrates removal of a substrate, according to an exemplary embodiment;

FIGS. 18 and 19 each illustrates a cross-sectional view of the semiconductor structure along section lines Y1-Y1 and Y2-Y2, respectively, and illustrates formation of a second inter-layer dielectric, according to an exemplary embodiment;

FIGS. 20 and 21 each illustrates a cross-sectional view of the semiconductor structure along section lines Y1-Y1 and Y2-Y2, respectively, and illustrates removal of a place holder, according to an exemplary embodiment; and

FIGS. 22 and 23 each illustrates a cross-sectional view of the semiconductor structure along section lines Y1-Y1 and Y2-Y2, respectively, and illustrates formation of a third inter-layer dielectric and a contact, according to an exemplary embodiment.

The drawings are not necessarily to scale. The drawings are merely schematic representations, not intended to portray specific parameters of the invention. The drawings are intended to depict only typical embodiments of the invention. In the drawings, like numbering represents like elements.

### DETAILED DESCRIPTION

Detailed embodiments of the claimed structures and methods are disclosed herein; however, it can be understood that the disclosed embodiments are merely illustrative of the claimed structures and methods that may be embodied in various forms. This invention may, however, be embodied in many different forms and should not be construed as limited to the exemplary embodiment set forth herein. Rather, these exemplary embodiments are provided so that this disclosure will be thorough and complete and will fully convey the scope of this invention to those skilled in the art. In the description, details of well-known features and techniques may be omitted to avoid unnecessarily obscuring the presented embodiments.

For purposes of the description hereinafter, the terms “upper”, “lower”, “right”, “left”, “vertical”, “horizontal”, “top”, “bottom”, and derivatives thereof shall relate to the disclosed structures and methods, as oriented in the drawing figures. The terms “overlying”, “atop”, “on top”, “positioned on” or “positioned atop” mean that a first element, such as a first structure, is present on a second element, such as a second structure, wherein intervening elements, such as an interface structure may be present between the first element and the second element. The term “direct contact” means that a first element, such as a first structure, and a second element, such as a second structure, are connected without any intermediary conducting, insulating or semiconductor layers at the interface of the two elements.

In the interest of not obscuring the presentation of embodiments of the present invention, in the following detailed description, some processing steps or operations that are known in the art may have been combined together for presentation and for illustration purposes and in some instances may have not been described in detail. In other instances, some processing steps or operations that are known in the art may not be described at all. It should be understood that the following description is rather focused on the distinctive features or elements of various embodiments of the present invention.

The present invention relates, generally, to the field of semiconductor manufacturing, and more particularly to a metal-insulator-metal (hereinafter “MIM”) capacitor.

A field effect transistor (hereinafter “FET”) may be used as a capacitor for various functions in digital and analog circuits. There are some negative effects of using a FET as a capacitor. A first negative effect is that the capacitance of an FET varies nonlinearly depending on a bias applied to the FET. A second negative effect of using an FET as a capacitor is that this requires a large portion of real estate of the semiconductor device.

A MIM capacitor is formed by adding extra masks between the wire metal layers. The MIM capacitor has advantages over an FET capacitor. A first advantage is the MIM capacitor has constant capacitance constant over a varied applied input voltage. A second advantage is the MIM capacitor has a highly linear nature and dynamic range. The highly linear nature of the MIM capacitor means that capacitance will not change based on bias. An FET capacitor changes value with bias. This is a greater benefit for circuit design and modeling of functionality of the whole circuit.

The capacitance density MIM capacitor may have a compatible capacitance to an FET capacitance. A capacitance density is a capacitance divided by area. The MIM capacitor is formed at a high BEOL level, requiring a large process overhead. A large process overhead means high parallel capacitance during entirety of BEOL process steps and higher metal levels.

In this invention, the MIM capacitor is placed adjacent to normal function FETs of the semiconductor device. Placing the MIM capacitor close to the normal function FETs improves alternating current (AC) performance by providing a lower parallel resistance from the whole BEOL, and provides an improvement on area scaling to increase capacity density.

When a MIM capacitor is formed at a high level of the BEOL, there may be additional or parallel capacitance due to wiring, which can affect functionality of a circuit. Parallel capacitance is un-intended capacitance. By having the MIM capacitor adjacent to other electronic components of a circuit, there is less parallel capacitance.

In this invention, a buried power rail trench is formed between adjacent nanosheet stacks. The MIM capacitor is formed in the buried power rail trench. A buried power rail trench is a trench formed and connected for a power rail. The MIM capacitor may be formed between either adjacent single nanosheet stacks or may be formed between adjacent double nanosheet stacks.

A first terminal or contact to the MIM capacitor may be connected to bottom wiring of a semiconductor device and a second terminal or contact to the MIM capacitor may be connected to upper wiring of the semiconductor device, above the nanosheet FET. The first and second terminals or contacts may also be referred to as an anode and cathode.

In an alternate embodiment, the MIM capacitor may be formed in a buried power rail trench between any adjacent normal function devices on the semiconductor device. This is not limited to nanosheet FETS.

An advantage of forming the MIM capacitor in a buried power rail trench between adjacent normal function devices includes improved performance of the normal function devices due to the proximity of the MIM capacitor. An additional advantage is a high capacitance density and a third advantage is lower sensitivity to process defects such as shorts.

The MIM capacitor in a buried power rail trench in stacked nanosheet FET has a high capacity due to a large surface area over a height of the MIM capacitor. The height of the MIM capacitor can be greater than a height of the stacked nanosheet FET.

The present invention relates, generally, to the field of semiconductor manufacturing, and more particularly to a metal-insulator-metal (MIM) capacitor.

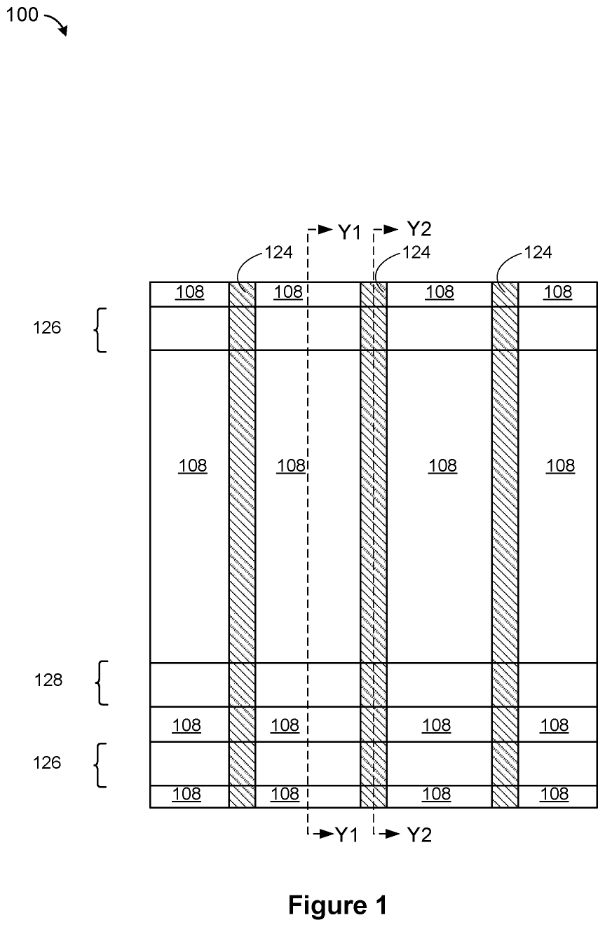

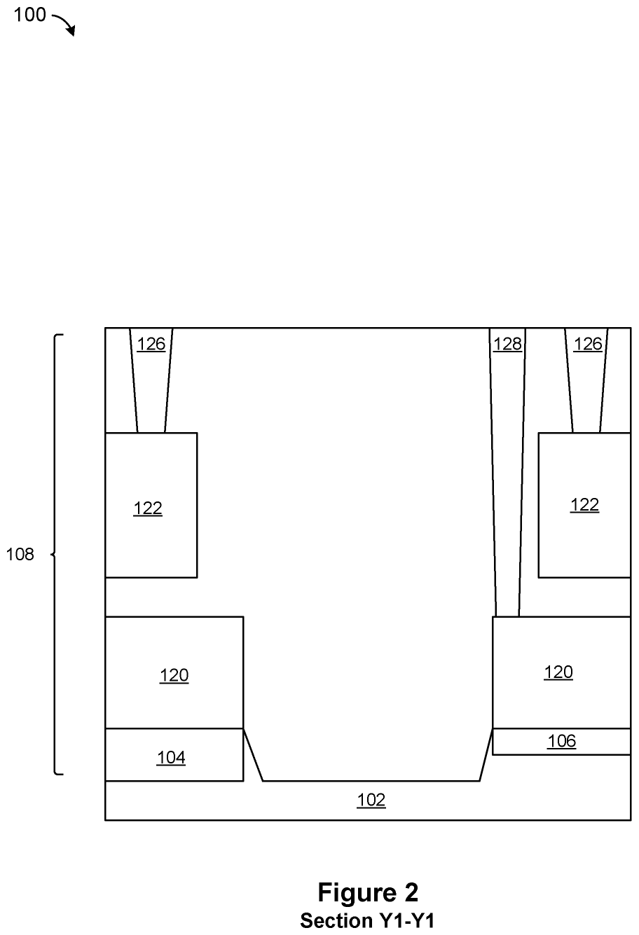

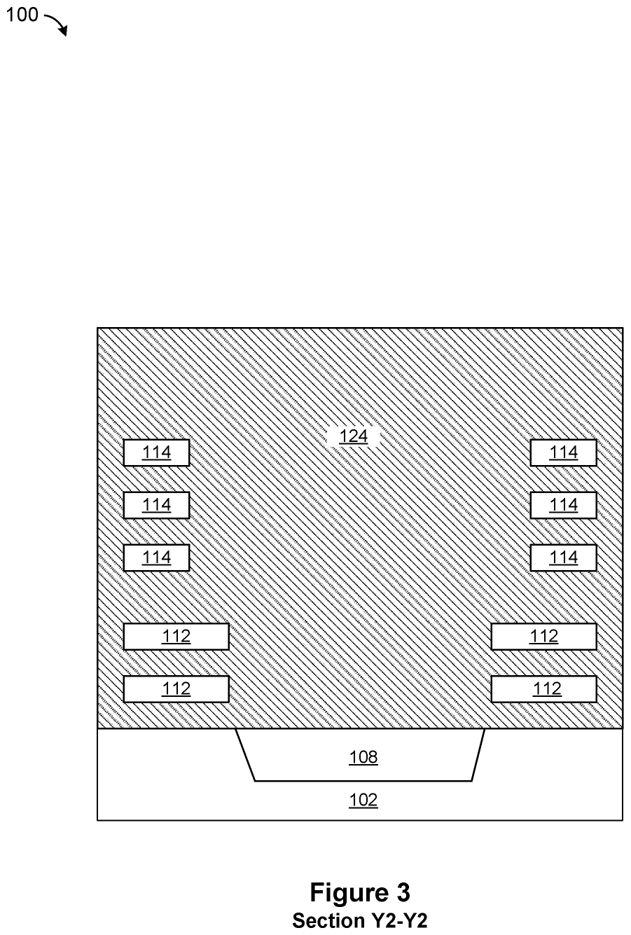

Referring now to FIGS. 1, 2 and 3, a semiconductor structure 100 (hereinafter “structure”) at an intermediate stage of fabrication is shown according to an exemplary embodiment. FIG. 1 is a top view of the structure 100. FIG. 2 is a cross-sectional view of the structure 100 along section line Y1-Y1. FIG. 3 is a cross-sectional view of the structure 100 along section line Y2-Y2. FIGS. 2 and 3 are parallel to each other. The structure 100 may be formed or provided.

Several steps have been completed to form the structure 100 of FIGS. 1, 2, 3. The structure 100 may include a substrate 102, a place holder 104, an etch stop layer 106, an inter-layer dielectric (hereinafter “ILD”) 108, a semiconductor channel layer 112, a semiconductor channel layer 114, a source drain 120, a source drain 122, a replacement gate 124, a contact 126 and a contact 128. The structure 100 may have an upper region 103 and a lower region 101.

The structure 100 may have had alternating layers of sacrificial semiconductor material (not shown) and semiconductor channel material stacked one on top of another on the substrate 102. The substrate 102 may be, for example, a bulk substrate, which may be made from any of several known semiconductor materials such as, for example, silicon, germanium, silicon-germanium alloy, and compound (e.g. III-V and II-VI) semiconductor materials. Non-limiting examples of compound semiconductor materials include gallium arsenide, indium arsenide, and indium phosphide, or indium gallium arsenide. Typically, the substrate 102 may be approximately, but is not limited to, several hundred microns thick. In other embodiments, the substrate 102 may be a layered semiconductor such as a silicon-on-insulator or SiGe-on-insulator, where a buried insulator layer, separates a base substrate from a top semiconductor layer. The substrate 102 may have the place holder 104 and the etch stop layer 106 embedded in the substrate 102. The place holder 104 may contain silicon germanium. The etch stop layer 106 may contain silicon germanium. The place holder 104 and the etch stop layer 106 may contain different materials which allow selective removal during subsequent processing steps.

The alternating layers of sacrificial semiconductor material (not shown) and semiconductor channel material may have included a sacrificial semiconductor material layer (hereinafter “sacrificial layer”) (not shown), covered by a semiconductor channel material layer 112 (hereinafter “channel layer”), covered by a sacrificial layer (not shown), covered by a channel layer 112, covered by a sacrificial layer (not shown), covered by a sacrificial layer (not shown), covered by a channel layer 114, covered by a sacrificial layer (not shown), covered by a sacrificial layer (not shown), covered by a channel layer 114, covered by a sacrificial layer (not shown), covered by a sacrificial layer (not shown), covered by a channel layer 114, covered by a sacrificial layer (not shown). It should be noted that, while a limited number of alternating layers are depicted, any number of sacrificial layers (not shown), channel layers 112 and channel layers 114 may be formed.

The terms “epitaxially growing and/or depositing” and “epitaxially grown and/or deposited” mean the growth of a semiconductor material on a deposition surface of a semiconductor material, in which the semiconductor material being grown has the same crystalline characteristics as the semiconductor material of the deposition surface. In an epitaxial deposition technique, the chemical reactants provided by the source gases are controlled and the system parameters are set so that the depositing atoms arrive at the deposition surface of the semiconductor substrate with sufficient energy to move around on the surface and orient themselves to the crystal arrangement of the atoms of the deposition surface. Therefore, an epitaxial semiconductor material has the same crystalline characteristics as the deposition surface on which it is formed.

Examples of various epitaxial growth techniques include, for example, rapid thermal chemical vapor deposition (RTCVD), low-energy plasma deposition (LEPD), ultra-high vacuum chemical vapor deposition (UHVCVD), low pressure chemical vapor deposition (LPCVD), atmospheric pressure chemical vapor deposition (APCVD) and molecular beam epitaxy (MBE). The temperature for epitaxial deposition typically ranges from approximately 550° C. to approximately 900° C. Although higher temperature typically results in faster deposition, the faster deposition may result in crystal defects and film cracking. The epitaxial growth the first and second semiconductor materials that provide the sacrificial semiconductor material layers and the semiconductor channel material layers, respectively, can be performed utilizing any well-known precursor gas or gas mixture. Carrier gases like hydrogen, nitrogen, helium and argon can be used.

Each sacrificial layer (not shown), is composed of a first semiconductor material which differs in composition from at least an upper portion of the substrate 102, the channel layer 112 and the channel layer 114. In an embodiment, each sacrificial layer (not shown), may be a silicon-germanium semiconductor alloy and have a germanium concentration less than 50 atomic percent. In another example, each sacrificial layer (not shown), may have a germanium concentration ranging from about 20 atomic percent to about 40 atomic percent. Each sacrificial layer (not shown) can be formed using known deposition techniques or an epitaxial growth technique as described above.

Each channel layer 112 is composed of a second semiconductor material which differs in composition from at least the upper portion of the substrate 102 and the sacrificial layer (not shown). Each channel layer 112 has a different etch rate than the first semiconductor material of sacrificial layer (not shown). The second semiconductor material can be, for example, silicon. The second semiconductor material, for each channel layer 112 can be formed using known deposition techniques or an epitaxial growth technique as described above. Each channel layer 114 may be a different semiconductor material than the channel layers 112 or may be the same semiconductor material as the channel layers 112.

The alternating layers of sacrificial layer (not shown), the channel layers 112 and the channel layers 114 can be formed by sequential epitaxial growth of alternating layers of the first semiconductor material, the second semiconductor material and the bottom sacrificial layer (not shown).

The sacrificial layers (not shown) may have a thickness ranging from about 5 nm to about 15 nm, and the channel layers 112, 114 may have a thickness ranging from about 3 nm to about 15 nm. Each sacrificial layer (not shown) may have a thickness that is the same as, or different from, a thickness of each channel layer 112, 114. In an embodiment, each sacrificial layer (not shown) has an identical thickness. In an embodiment, each channel layer 112 has an identical thickness. In an embodiment, each channel layer 114 has an identical thickness.

The alternating layers of sacrificial layers (not shown), channel layers 112 and channel layers 114 may be formed into nanosheet fins, by methods known in the arts and include steps such as forming a hard mask (not shown) on the alternating layers, patterning the hard mask (not shown). The hard mask (not shown) may be removed.

The upper region 103 may include an area surrounding the channel layers 114. The lower region 101 may include an area surrounding the channel layers 112.

The lower region 101 can include any number of channel layers 112. The upper region 103 can include any number of channel layers 114. The nanosheet stack of the upper region 103 is vertically aligned above the nanosheet stack of the lower region 101 is used to produce a gate all around device that includes vertically stacked semiconductor channel material nanosheets for a pair of stacked field effect transistors (hereinafter “FET”). In an embodiment, the lower region 101 may be an n-FET region and the upper region 103 may be a p-FET region. In an alternate embodiment, the lower region 101 may be a p-FET region and the upper region 103 may be an n-FET region. Alternatively, both the upper region 103 and the lower region 101 may be p-FET or may both be n-FET. In an embodiment, there may be only a lower region 101 which can be either an n-FET region or a p-FET region.

The sacrificial gate (not shown) is formed orthogonal (perpendicular) to the nanosheet stacks. The sacrificial gate (not shown) may include a single sacrificial material or a stack of two or more sacrificial materials. The at least one sacrificial material can be formed by forming a blanket layer (or layers) of a material (or various materials) and then patterning the material (or various materials) by lithography and an etch. The sacrificial gate (not shown) can include any material including, for example, polysilicon, amorphous silicon, or multilayered combinations thereof. The sacrificial gate (not shown) can be formed using any deposition technique including, for example, chemical vapor deposition (CVD), physical vapor deposition (PVD), high density plasma (HDP) deposition, and spin on techniques. Optionally, a gate dielectric layer (not shown) and a gate cap (not shown) may be formed as part of the sacrificial gate (not shown) in accordance with known techniques.

In an embodiment, the sacrificial gate (not shown) is deposited with a thickness sufficient to fill, or substantially fill, the spaces between adjacent nanosheet structures and cover horizontal upper surfaces of the substrate 102, the place holder 104, the etch stop layer 106 and the ILD 108. The sacrificial gate (not shown) may be adjacent to vertical side surfaces of the nanosheet stack. The sacrificial gate (not shown) may cover an upper horizontal surface of an uppermost channel layer 114 of the nanosheet stack. A height of the sacrificial gate (not shown) may be much thicker than the underlying structure and may have a height between 100 nm and 150 nm about the nanosheet stack. A gate cap (not shown) may cover an upper horizontal surface and a vertical side surface of the sacrificial gate (not shown).

Portions of the sacrificial layers (not shown) may be selectively removed using known techniques. For example, a wet or dry etch process can be used with the appropriate chemistry to remove portions of each of the sacrificial layers (not shown). The material used for the etching process may be selective such that the channel layers 112, the channel layers 114, the sacrificial gate (not shown), the place holder 104, the etch stop layer 108 and the substrate 102 remain and are not etched. After etching, portions of the sacrificial layers (not shown) covered on opposite sides by the sacrificial gate (not shown) may remain as part of the nanosheet stack. In such cases, the sacrificial gate (not shown) supports the remaining channel layers 112, 114 of the nanosheet stack.

The source drain 120 and the source drain 122 may each be grown separately by methods known in the arts. For example, the source drain 120 may be first formed, a dielectric such as the ILD 108, may be formed above the source drain 120, and the source drain 122 may be formed.

The source drain 120 and the source drain 122 may each be epitaxially grown surrounding a vertical portion of the nanosheet stack on opposite sides of the sacrificial gate (not shown) on the place holder 104, the etch stop layer 106 and the substrate 102. The source drain 120 may surround the channel layers 112 in the lower region 101 of the nanosheet stack. The source drain 122 may surround the channel layers 114 in the upper region 103 of the nanosheet stack.

The ILD 108 may be formed by depositing or growing a dielectric material, followed by a combination of CMP and dry/wet etch and recessing steps on structure 100. The ILD 108 may be deposited using typical deposition techniques, for example, atomic layer deposition (ALD), molecular layer deposition (MLD), chemical vapor deposition (CVD), physical vapor deposition (PVD), high density plasma (HDP) deposition, and spin on techniques, followed by an etch process such as wet etch or a reactive ion etch (RIE), or any suitable etch process. In an embodiment, the ILD 108 may include one or more layers. In an embodiment, the ILD 108 may include any dielectric material such as silicon oxide, silicon oxynitride, silicon nitride, SiBCN, SiOC, low-k dielectric or any combination of these materials. In an embodiment, the ILD 108 may be a nitride. In an alternate embodiment, the ILD 108 may be an oxide.

The sacrificial gate (not shown) may be removed by methods known in the arts. The sacrificial layers (not shown) may be removed by methods known in the arts. The sacrificial gate (not shown) and the sacrificial layers (not shown) may be removed simultaneously or consecutively. The sacrificial gate (not shown) and the sacrificial layers (not shown) are removed selective to the channel layers 112, 114, the ILD 108, the source drain 120, the source drain 122, the place holder 104, the etch stop layer 106 and the substrate 102. For example, a dry etch process can be used to selectively remove the sacrificial gate (not shown) and the sacrificial layers (not shown), such as using vapor phased HCl dry etch. An upper surface and a lower surface of the channel layers 112, 114 may be exposed.

The replacement gate 124 may be conformally formed on the structure 100, according to an exemplary embodiment. The replacement gate 124 is formed in each cavity of the nanosheet stack and surrounding suspended portions of the channel layers 112, 114. The replacement gate 124 forms a layer surrounding exposed portions of the nanosheet stacks. The replacement gate 124 may cover vertical side surfaces, an upper horizontal surface and a lower horizontal surface of the channel layers 112, 114.

The replacement gate 124 may be deposited using typical deposition techniques, for example, atomic layer deposition (ALD), molecular layer deposition (MLD), and chemical vapor deposition (CVD). In an embodiment, the replacement gate 124 may include more than one layer, for example, a conformal layer of a high-k dielectric material such as HfO₂, ZrO₂, La₂O₃, Al₂O₃, TiO₂, SrTiO₃, LaAlO₃, Y₂O₃, HfOₓN_{y}, ZrOₓN_{y}, La₂OₓN_{y}, Al₂OₓN_{y}, TiOₓN_{y}, SrTiOₓN_{y}, LaAlOₓN_{y}, Y₂OₓN_{y}, SiON, SiNₓ, a silicate thereof, and an alloy thereof. In an embodiment, a work function metal of a p-FET device may include a metal nitride, for example, titanium nitride or tantalum nitride, titanium carbide titanium aluminum carbide, or other suitable materials known in the art. In an embodiment, the work function metal of an n-FET device may include, for example, titanium aluminum carbide or other suitable materials known in the art. In an embodiment, the work function metal may include one or more layers to achieve desired device characteristics.

In an embodiment, the replacement gate 124 of the upper region 103 may include a different material than the replacement gate 124 of the lower region 101.

A chemical mechanical polishing (CMP) technique may be used to remove excess material and polish upper surfaces of the structure 100. An upper surface of the structure 100 may include horizontal surfaces of the ILD 108 and the replacement gate 124.

Openings (not shown) may be formed in the ILD 108. A first opening (not shown) may expose an upper horizontal surface of the source drain 120. The contact 128 may be formed in the first opening (not shown) which exposes the upper horizontal surface of the source drain 120. A second opening (not shown) may expose an upper horizontal surface of the source drain 122. The contact 126 may be formed in the second opening (not shown) which exposes the upper horizontal surface of the source drain 122. The contacts 126, 128 may be formed by methods known in the arts.

A chemical mechanical polishing (CMP) technique may be used to remove excess material and polish upper surfaces of the structure 100. An upper surface of the structure 100 may include horizontal surfaces of the ILD 108, the replacement gate 124 and the contacts 126, 128.

There may be any number of nanosheet stacks on the structure 100.

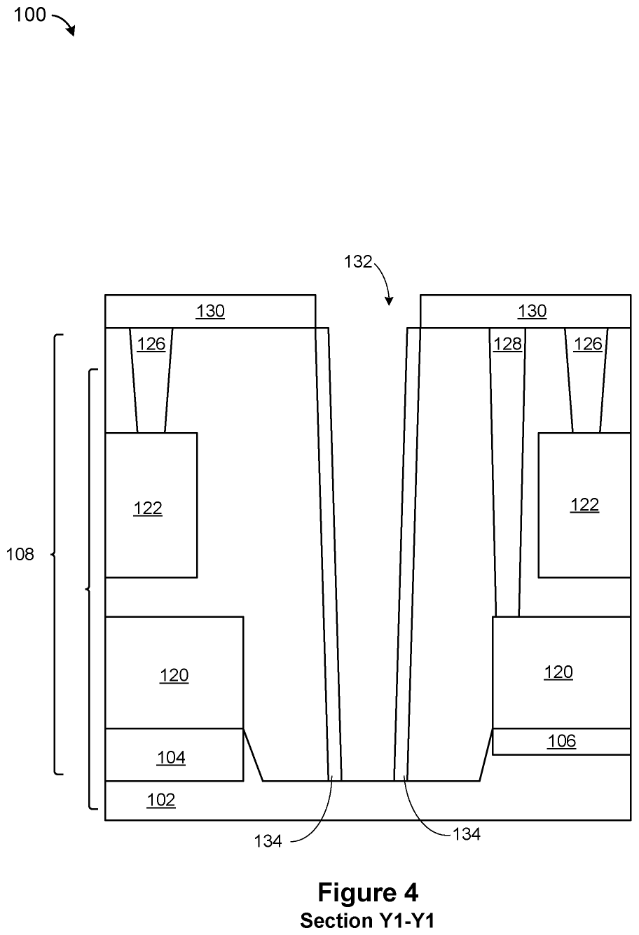

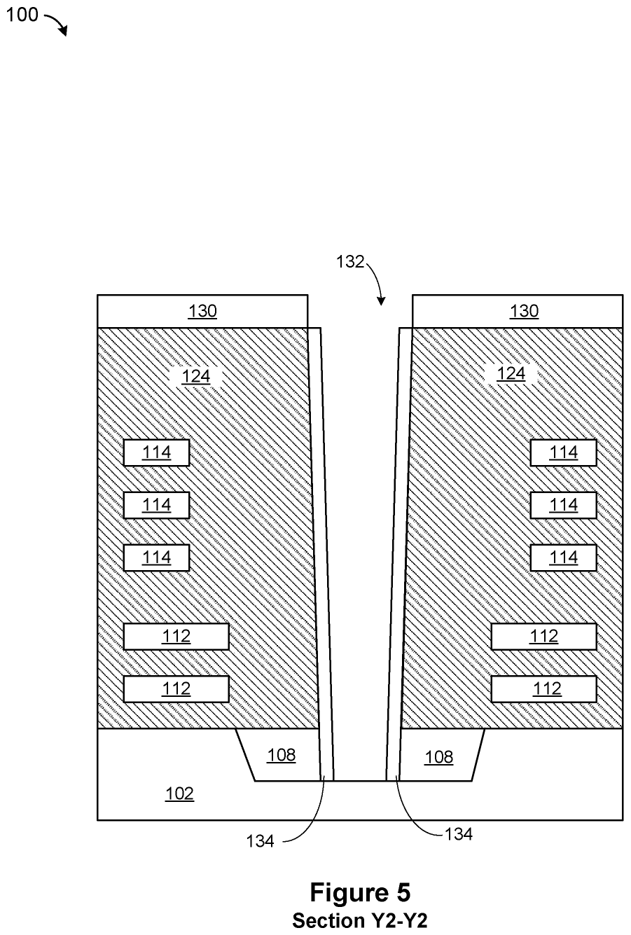

Referring now to FIGS. 4 and 5, the structure 100 is shown according to an exemplary embodiment. FIG. 4 is a cross-sectional view of the structure 100 along section line Y1-Y1. FIG. 5 is a cross-sectional view of the structure 100 along section line Y2-Y2. FIGS. 4 and 5 are parallel to each other. A hard mask 130 may be formed. A trench 132 may be formed. A liner 134 may be formed.

The hard mask 130 may be formed and patterned. The trench 132 may be formed by removal of portions of the ILD 108 and portions of the replacement gate 124. The trench 132 may be formed between each nanosheet stack by an anisotropic etching technique, such as, for example, reactive ion etching (RIE), and stopping on etching a portion of the substrate 102. A vertical side surface of the trench 132 may include the replacement gate 124 and the ILD 108.

The liner 134 may be conformally deposited on the structure 100. The liner 134 may be formed by depositing or growing a dielectric material on the structure 100. The liner 134 may be deposited using typical deposition techniques, for example, atomic layer deposition (ALD), molecular layer deposition (MLD), chemical vapor deposition (CVD), physical vapor deposition (PVD), high density plasma (HDP) deposition, and spin on techniques. In an embodiment, the liner 134 may include any dielectric material such as silicon oxide, silicon oxynitride, silicon nitride, SiBCN, SiOC, low-k dielectric or any combination of these materials. Portions of the liner 134 may be removed from the upper horizontal surface of the substrate 102 by an anisotropic etching technique, such as, for example, reactive ion etching (RIE), and stopping on etching a portion of the substrate 102. The liner 134 may be formed along vertical side surfaces of the trench 132, along vertical side surfaces of the replacement gate 124 and the ILD 108.

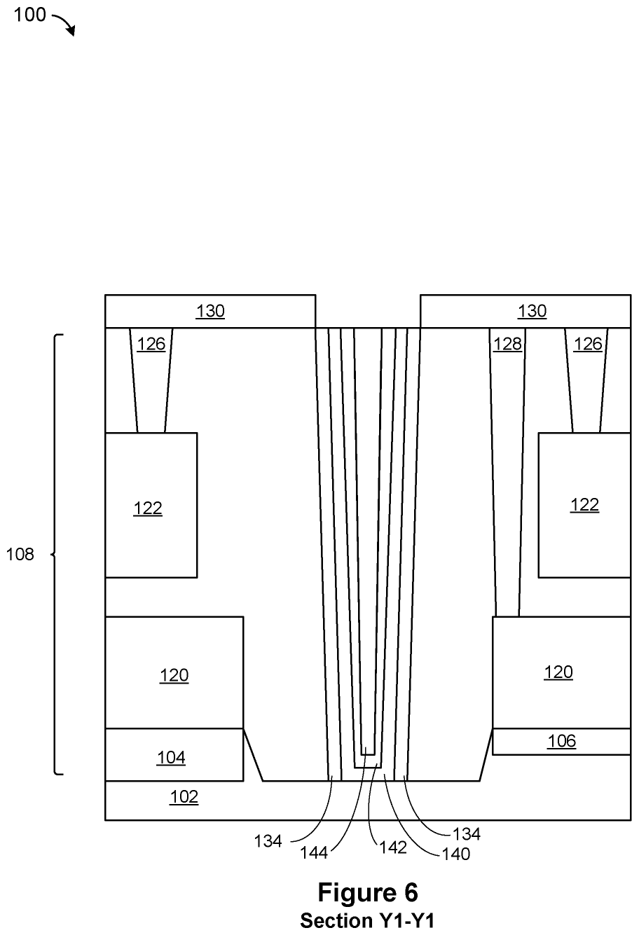

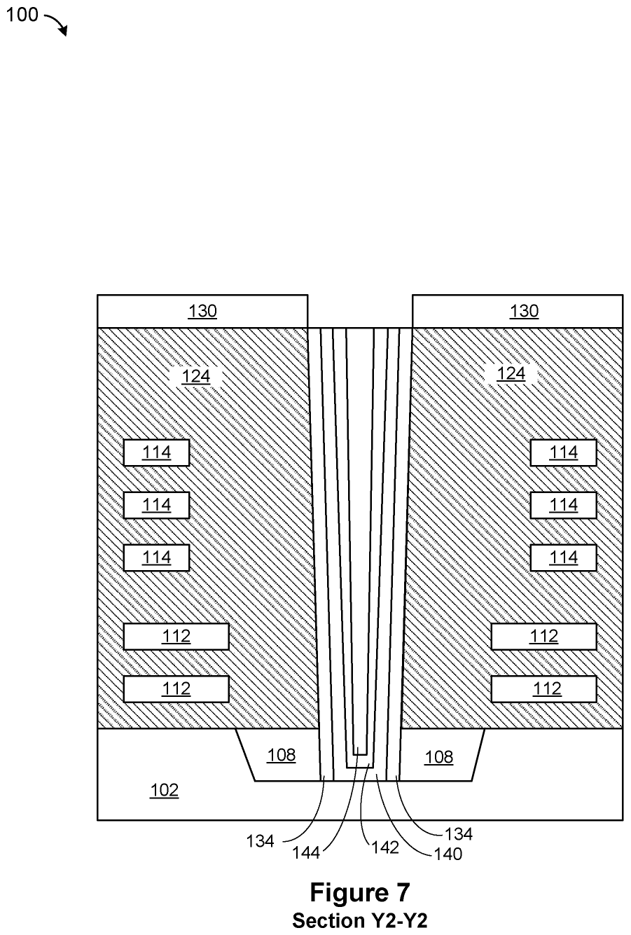

Referring now to FIGS. 6 and 7, the structure 100 is shown according to an exemplary embodiment. FIG. 6 is a cross-sectional view of the structure 100 along section line Y1-Y1. FIG. 7 is a cross-sectional view of the structure 100 along section line Y2-Y2. FIGS. 6 and 7 are parallel to each other. An outer plate 140, an insulator 142 and an inner plate 144 may be formed, forming a metal-insulator-metal (hereinafter “MIM”).

The outer plate 140 may be formed in the trench 132, along a vertical side surface of the liner 134 and on the upper horizontal surface of the substrate 102.

In an embodiment, the outer plate 140 is formed from a conductive material layer which is blanket deposited on top of the structure 100, and directly on vertical side surfaces of the liner 134, filling a portion of the trench 132. The conductive material layer may include materials such as, for example copper (Cu), ruthenium (Ru), tungsten (W), tantalum nitride (TaN) and titanium nitride (TiN). The conductive material can be formed by for example, electrochemical deposition (ECD), chemical vapor deposition (CVD), physical vapor deposition (PVD), and atomic layer deposition (ALD) or a combination thereof. The outer plate 140 is formed by damascene, or patterned from the conductive material layer, using known patterning and etching techniques.

The insulator 142 may be conformally deposited on the structure 100. The insulator 142 may be formed by depositing or growing a dielectric material on the structure 100. The insulator 142 may be deposited using typical deposition techniques, for example, atomic layer deposition (ALD), molecular layer deposition (MLD), chemical vapor deposition (CVD), physical vapor deposition (PVD), high density plasma (HDP) deposition, and spin on techniques. In an embodiment, the insulator 142 may include any high-k dielectrics include, but are not limited to, HfO₂, ZrO₂, La₂O₃, Al₂O₃, TiO₂, a high-k dielectric material (with k>4.0).

The inner plate 144 may be formed as described for the outer plate 140, blanket deposited on top of the structure 100, and directly on vertical side surfaces of the insulator 142, filling remaining portions of the trench 132.

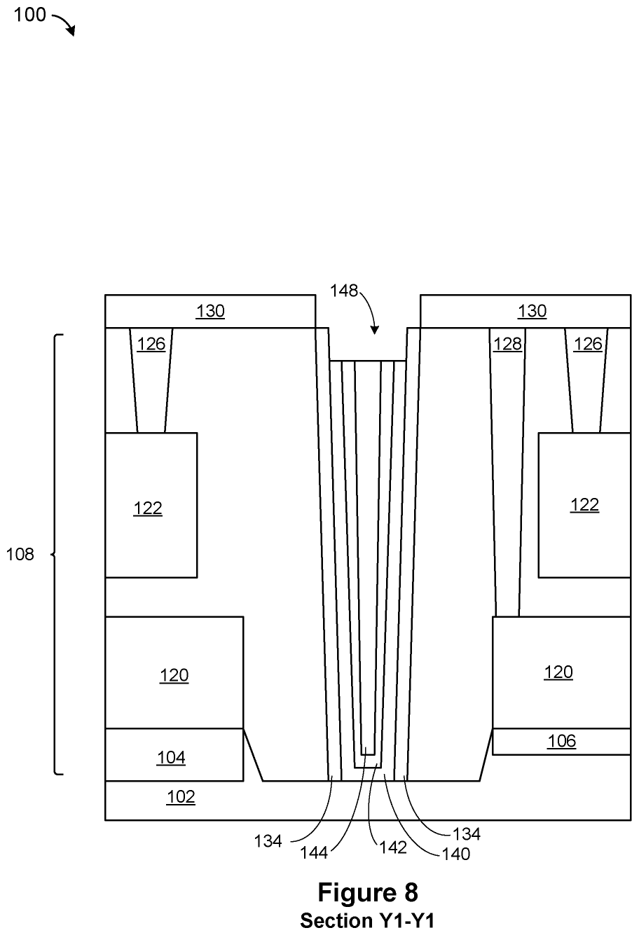

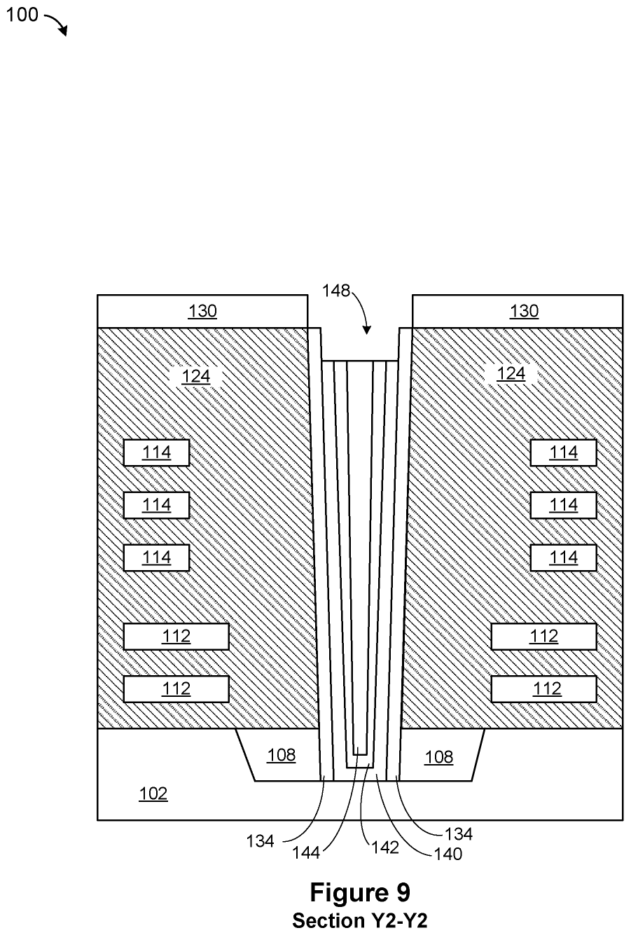

Referring now to FIGS. 8 and 9, the structure 100 is shown according to an exemplary embodiment. FIG. 8 is a cross-sectional view of the structure 100 along section line Y1-Y1. FIG. 9 is a cross-sectional view of the structure 100 along section line Y2-Y2. FIGS. 8 and 9 are parallel to each other. A portion of the inner plate 144, a portion of the insulator 142 and a portion of the outer plate 140 may be removed, forming a trench 148.

The trench 148 may be formed by an anisotropic etching technique, such as, for example, reactive ion etching (RIE), removing a portion of the inner plate 144, a portion of the insulator 142 and a portion of the outer plate 140. A horizontal upper surface of the inner plate 144, a horizontal upper surface of the insulator 142 and a horizontal upper surface of the outer plate 140 may form a lower horizontal surface of the trench 148. A vertical side surface of the liner 134 may exposed along the trench 148.

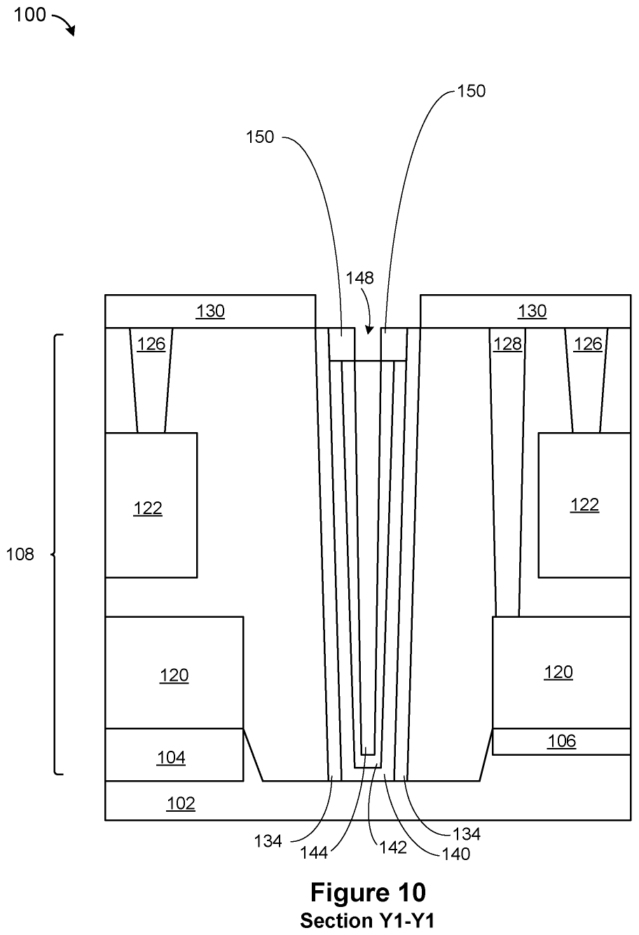

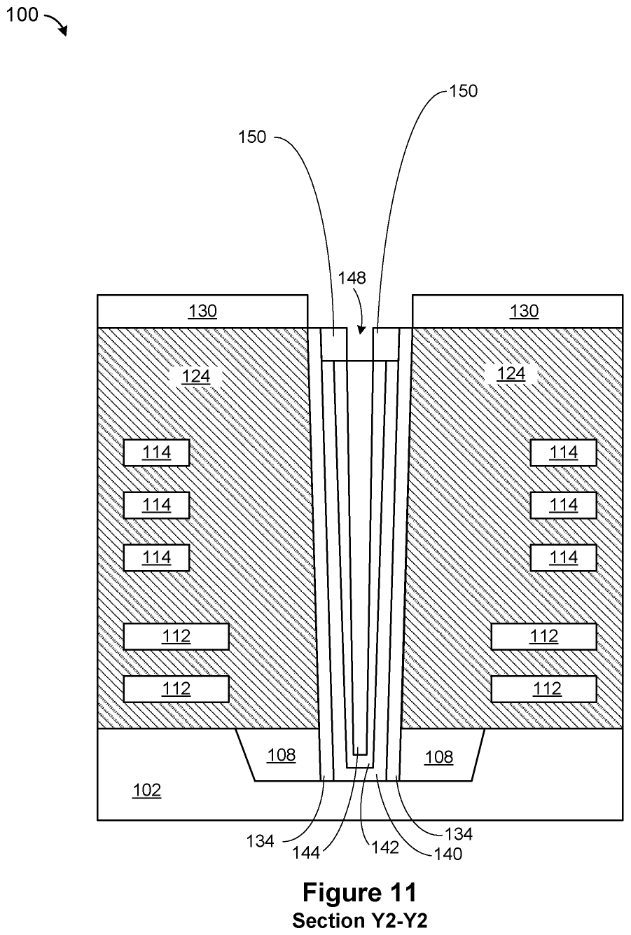

Referring now to FIGS. 10 and 11, the structure 100 is shown according to an exemplary embodiment. FIG. 10 is a cross-sectional view of the structure 100 along section line Y1-Y1. FIG. 11 is a cross-sectional view of the structure 100 along section line Y2-Y2. FIGS. 10 and 11 are parallel to each other. A dielectric spacer 150 may be formed.

The dielectric spacer may be formed in a portion of the trench 148.

The dielectric spacer 150 may be formed by depositing or growing a dielectric material, followed by a combination of CMP and dry/wet etch and recessing steps on structure 100. The dielectric spacer 150 may be formed as described for the ILD 108. The dielectric spacer 150 may be formed in the trench 148, on upper horizontal surfaces of the inner plate 144, the insulator 142 and the outer plate 140. A portion of the dielectric spacer 150 may be removed, by an anisotropic etching technique, such as, for example, reactive ion etching (RIE), exposing an upper horizontal surface of the inner plate 144. The dielectric spacer 150 may remain on the insulator 142 and the outer plate 140.

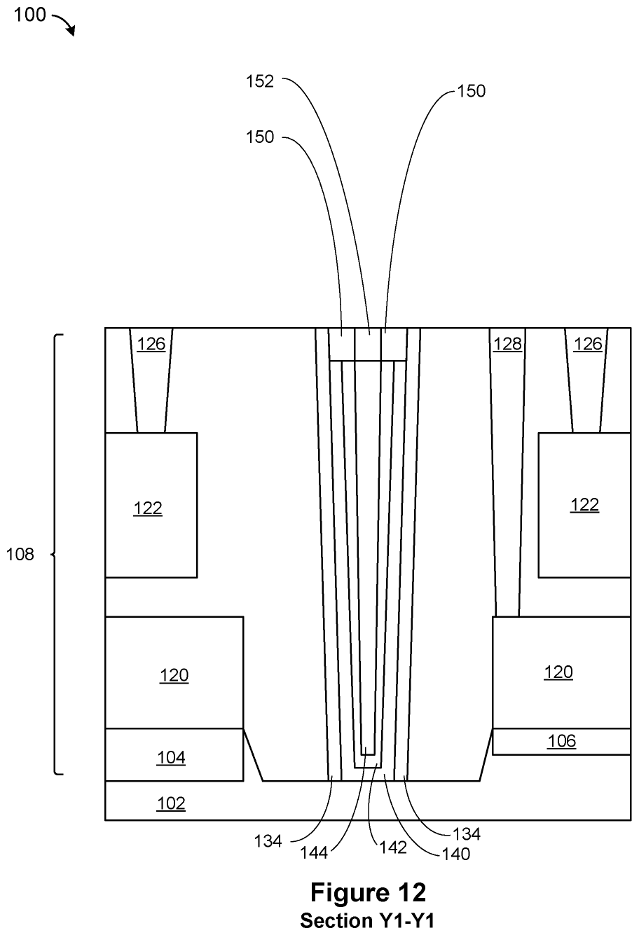

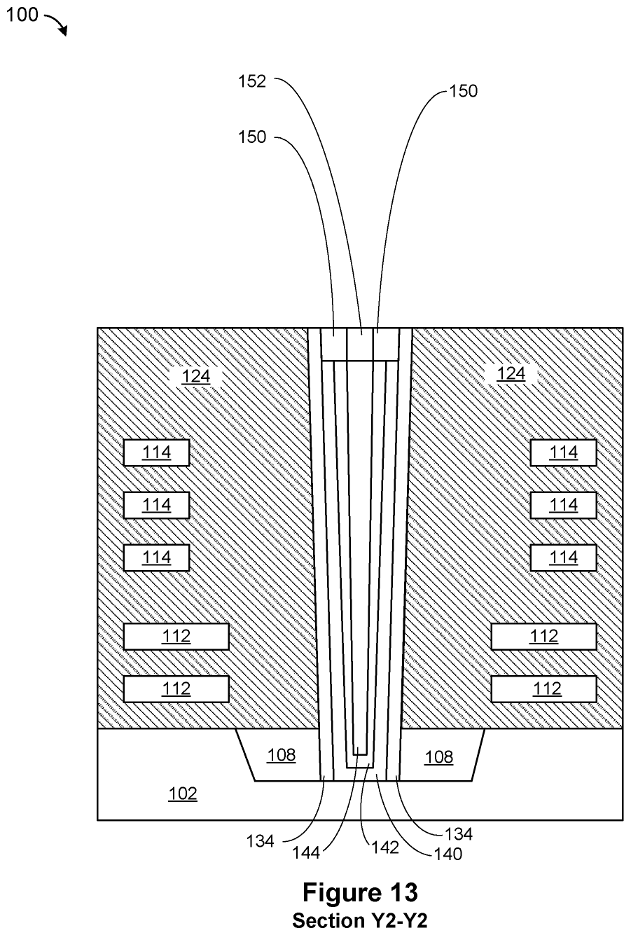

Referring now to FIGS. 12 and 13, the structure 100 is shown according to an exemplary embodiment. FIG. 12 is a cross-sectional view of the structure 100 along section line Y1-Y1. FIG. 13 is a cross-sectional view of the structure 100 along section line Y2-Y2. FIGS. 12 and 13 are parallel to each other. An inner plate metal 152 may be formed.

The inner plate metal 152 may be formed in remaining portions of the trench 148. The inner plate metal 152 may be formed as described for the outer plate 140. The inner plate metal 152 may provide a contact to the inner plate 144 of the MIM capacitor.

The inner plate metal 152 provides a contact to inner plate 144 of the MIM capacitor from an upper portion of the structure 100. Subsequent steps provide a contact to the outer plate 140 of the MIM capacitor from a lower portion of the structure 100.

A planarization process, such as, for example, chemical mechanical polishing (CMP), may be done to remove excess material from an upper horizontal surface of the structure 100 such that upper horizontal surfaces of the inner plate metal 152, the dielectric spacer 150, the liner 134, the replacement gate 124, the contacts 126, 128, and the ILD 108 are coplanar.

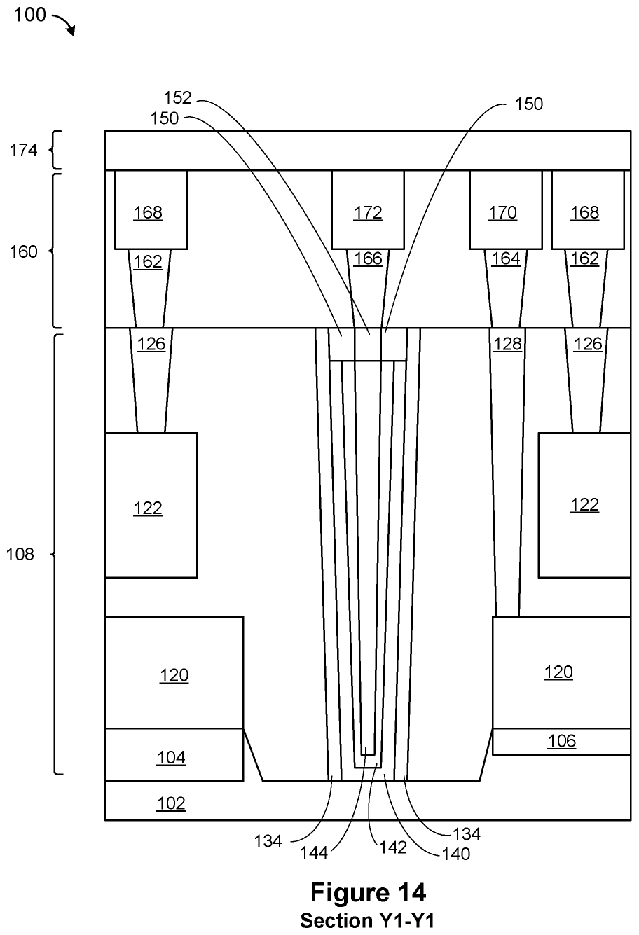

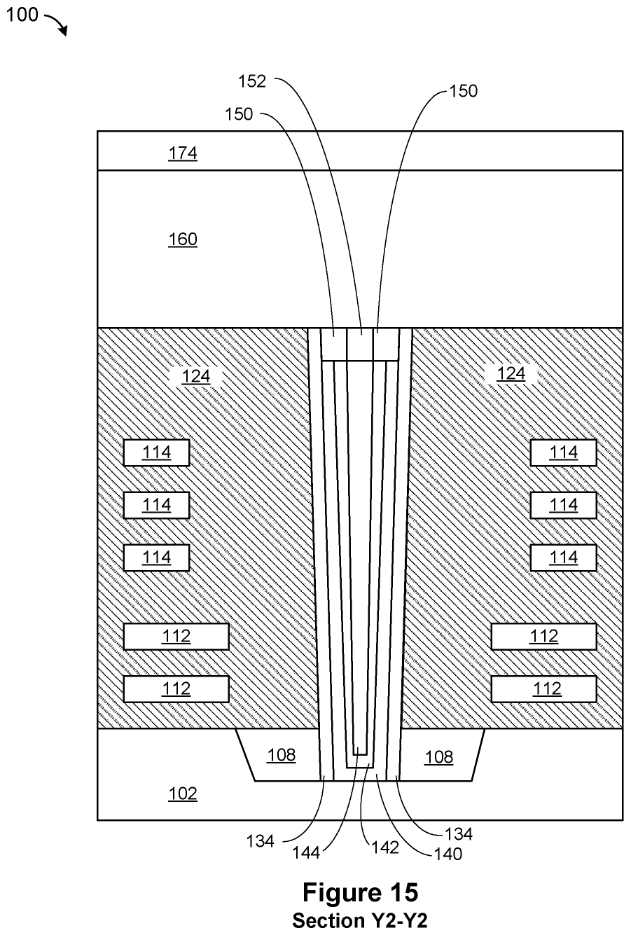

Referring now to FIGS. 14 and 15, the structure 100 is shown according to an exemplary embodiment. FIG. 14 is a cross-sectional view of the structure 100 along section line Y1-Y1. FIG. 15 is a cross-sectional view of the structure 100 along section line Y2-Y2. FIGS. 14 and 15 are parallel to each other. An inter-layer dielectric (hereinafter “ILD”) 160 may be formed, a via 162, a via 164, a via 166, an Mx metal line 168, an Mx metal line 170, an Mx metal line 172 and an inter-layer dielectric (hereinafter “ILD”) 174 may be formed.

The ILD 160 may be formed as described for the ILD 108, directly on an upper horizontal surface of the inner plate metal 152, the dielectric spacer 150, the liner 134, the replacement gate 124, the contacts 126, 128, and the ILD 108.

A planarization process, such as, for example, chemical mechanical polishing (CMP), may be done to remove excess material of the ILD 160 from an upper horizontal surface of the structure 100.

Openings (not shown) may be formed in the ILD 160. The via 162 may be formed in an opening which exposes an upper horizontal surface of the contact 126. The via 164 may be formed in an opening which exposes an upper horizontal surface of the contact 128. The via 166 may be formed in an opening which exposes an upper horizontal surface of the inner plate metal 152.

Trenches (not shown) may be formed in the ILD 160. The Mx metal line 168 may be formed in a trench which exposes an upper horizontal surface of the via 162. The Mx metal line 170 may be formed in a trench which exposes an upper horizontal surface of the via 164. The Mx metal line 172 may be formed in a trench which exposes an upper horizontal surface of the via 166.

In an embodiment, the vias 162, 164, 166 and the Mx metal lines 168, 170, 172 are formed from a conductive material layer which is blanket deposited on top of the structure 100, and directly on an upper horizontal surface of the ILD 160, filling the openings (not shown). The conductive material layer may include materials such as, for example copper (Cu), ruthenium (Ru), cobalt (Co), tungsten (W). The conductive material can be formed by for example, chemical vapor deposition (CVD), physical vapor deposition (PVD), and atomic layer deposition (ALD) or a combination thereof. The vias 162, 164, 166 and the Mx metal lines 168, 170, 172 are formed by damascene, or patterned from the conductive material layer, using known patterning and etching techniques. There may be any number of openings and trenches in the ILD 160, each filled with the vias 162, 164, 166 and the Mx metal lines 168, 170, 172 on the structure 100.

A planarization process, such as, for example, chemical mechanical polishing (CMP), may be done to remove excess material from an upper horizontal surface of the structure 100 such that upper horizontal surfaces of the vias 162, 164, 166, the Mx metal lines 168, 170, 172 and the ILD 160 are coplanar.

The ILD 174 may be formed as described for the ILD 108, directly on an upper horizontal surface of the vias 162, 164, 166, the Mx metal lines 168, 170, 172 and the ILD 160.

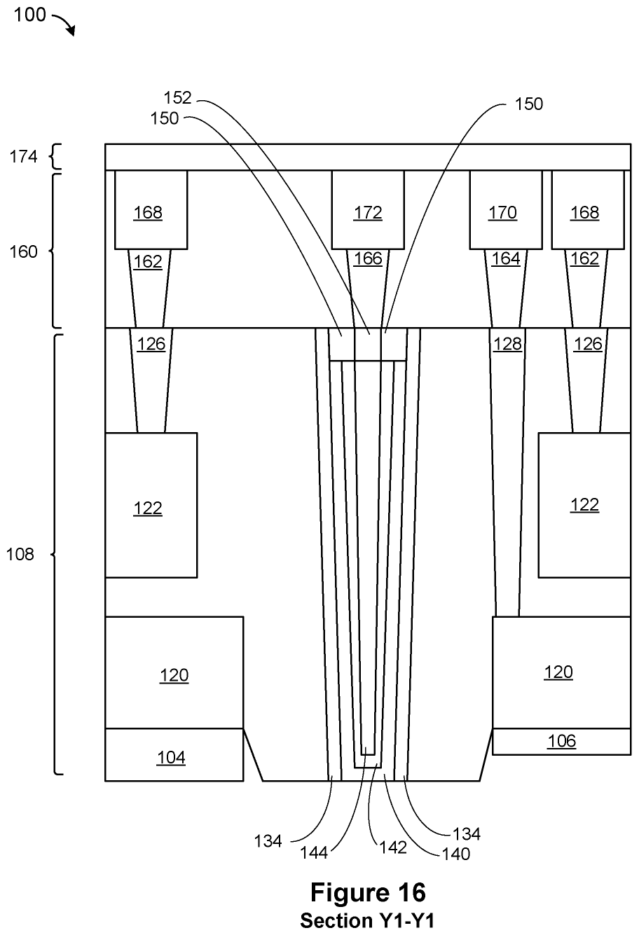

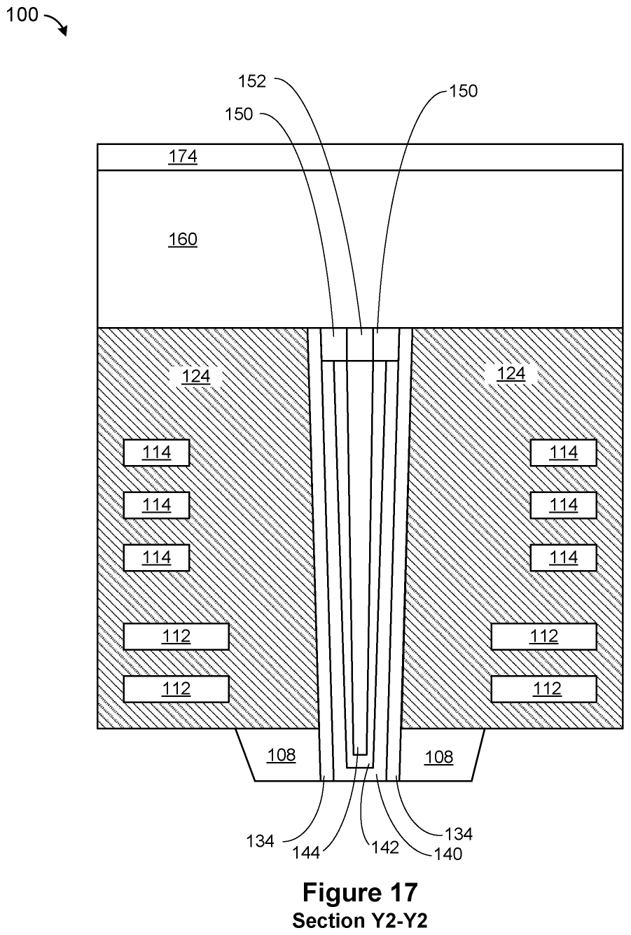

Referring now to FIGS. 16 and 17, the structure 100 is shown according to an exemplary embodiment. FIG. 16 is a cross-sectional view of the structure 100 along section line Y1-Y1. FIG. 17 is a cross-sectional view of the structure 100 along section line Y2-Y2. FIGS. 16 and 17 are parallel to each other. The structure 100 may be flipped and the silicon substrate 102 may be removed.

In an embodiment, a carrier wafer (not shown) is attached to an upper surface of the structure 100. The carrier wafer (not shown) may be attached using conventional wafer bonding process, such as dielectric-to-dielectric bonding or copper-to-copper bonding process.

The structure 100 may be physically turned such that the carrier wafer (not shown) is now at a bottom, allowing the processing of the structure to proceed at a lowest level of the structure. The following figures will not show the structure 100 flipped, however processing performed at the lowest level of the structure 100 is done while the structure 100 is flipped.

The silicon substrate 102 may be selectively removed exposing a lower horizontal surface of the replacement gate 124, a lower horizontal and vertical side surface of the ILD 108, a lower horizontal surface of the place holder 104, a lower horizontal and vertical side surface of the etch stop layer 106, a lower horizontal surface of the liner 134, and a lower horizontal surface of the outer plate 140. The silicon substrate 102 may be removed using a combination of processes steps, such as wafer grinding, CMP, RIE and wet etch process.

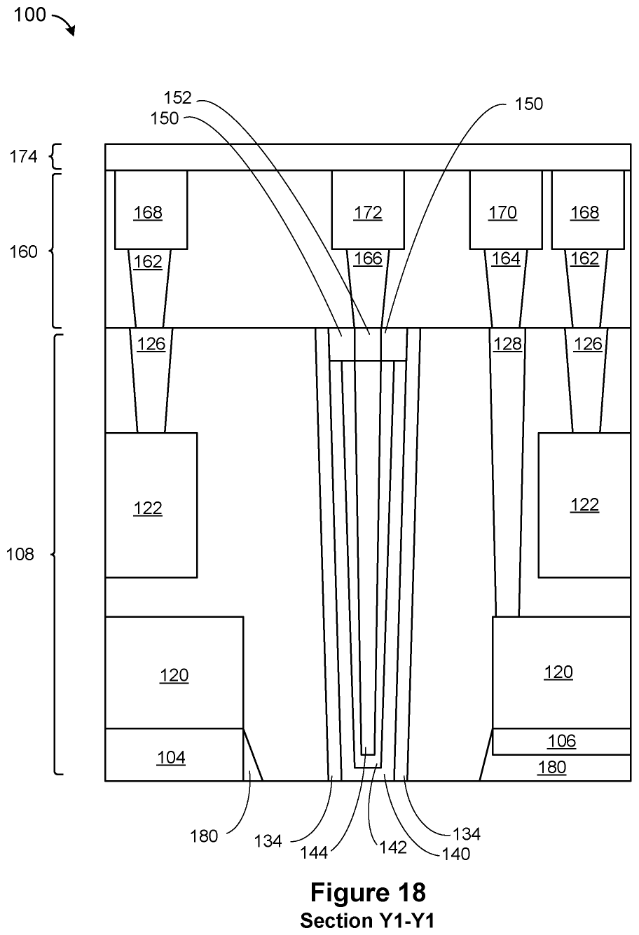

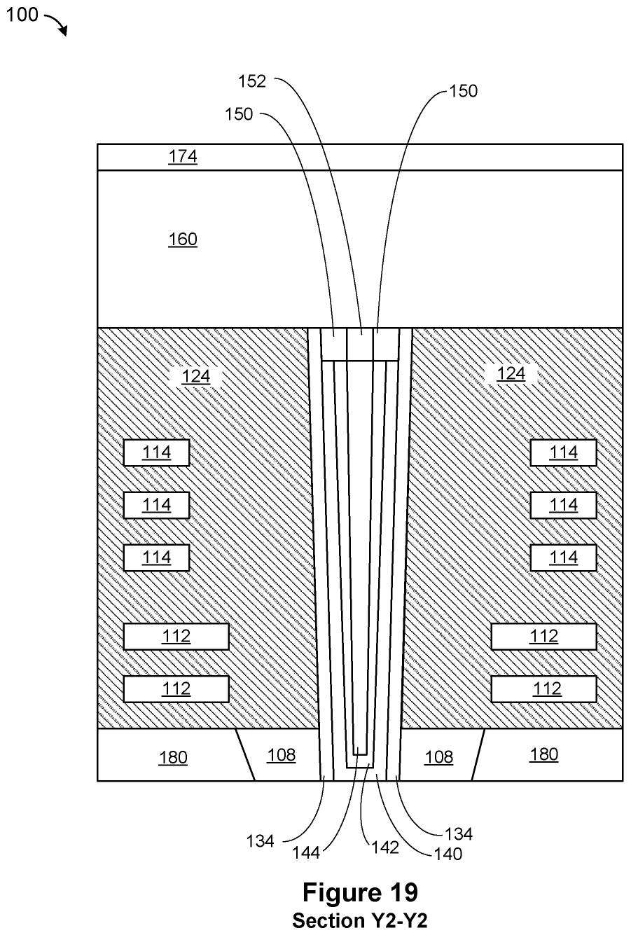

Referring now to FIGS. 18 and 19, the structure 100 is shown according to an exemplary embodiment. FIG. 18 is a cross-sectional view of the structure 100 along section line Y1-Y1. FIG. 19 is a cross-sectional view of the structure 100 along section line Y2-Y2. FIGS. 18 and 19 are parallel to each other. An inter-layer dielectric (hereinafter “ILD”) 176 may be formed.

The ILD 176 may be formed as described for the ILD 108 on a lower surface of the structure 100. The ILD 176 may be formed on the lower horizontal surface of the replacement gate 124, the lower horizontal and vertical side surface of the ILD 108, the lower horizontal surface of the place holder 104, the lower horizontal and vertical side surfaces of the etch stop layer 106, the lower horizontal surface of the liner 134, the lower horizontal surface of the outer plate 140 and the lower horizontal surface of the ILD 180.

A planarization process, such as, for example, chemical mechanical polishing (CMP), may be done to remove excess material from a lower horizontal surface of the structure 100 such that lower horizontal surfaces of the ILD 176, the place holder 104, the liner 134 and the outer plate 140 are coplanar.

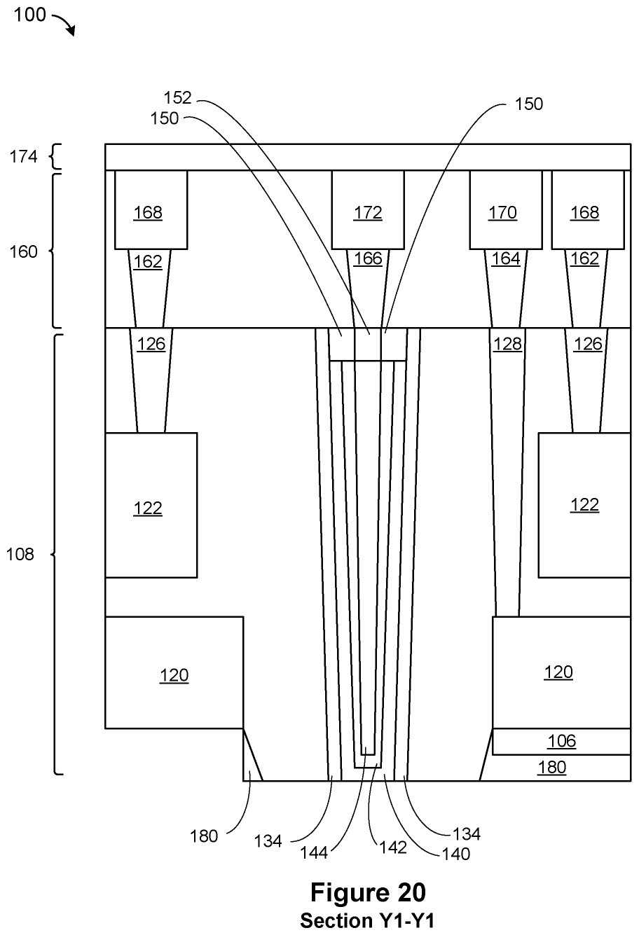

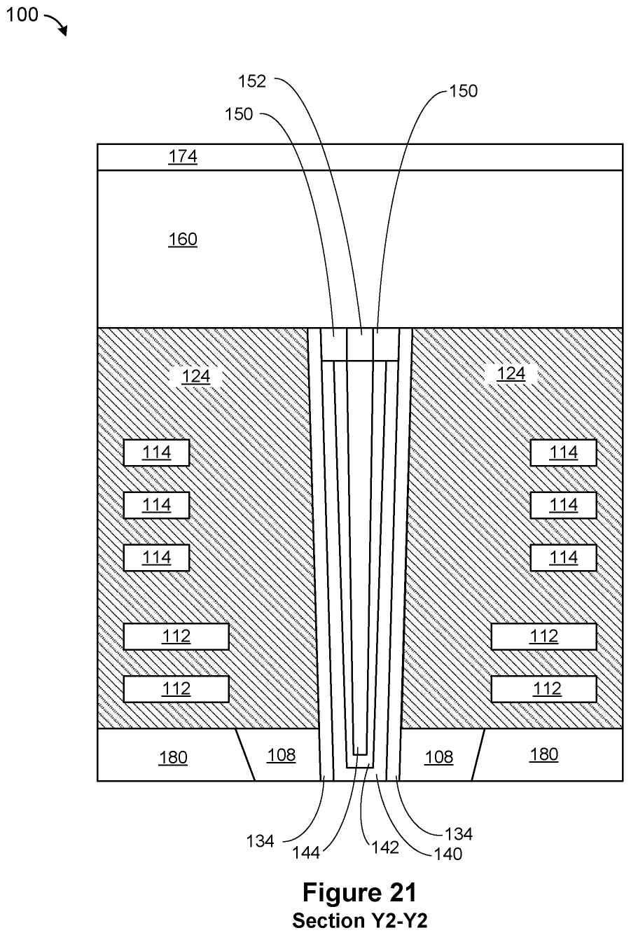

Referring now to FIGS. 20 and 21, the structure 100 is shown according to an exemplary embodiment. FIG. 20 is a cross-sectional view of the structure 100 along section line Y1-Y1. FIG. 21 is a cross-sectional view of the structure 100 along section line Y2-Y2. FIGS. 20 and 21 are parallel to each other. The place holder 104 may be removed.

Selective etching may be used to remove the place holder 104 and to expose a lower horizontal surface of the source drain 120 and a vertical side surface of the ILD 176. The material used for the etching process may be selective such that the ILD 176, the ILD 108, the liner 134 and the outer plate 144 remain and are not etched.

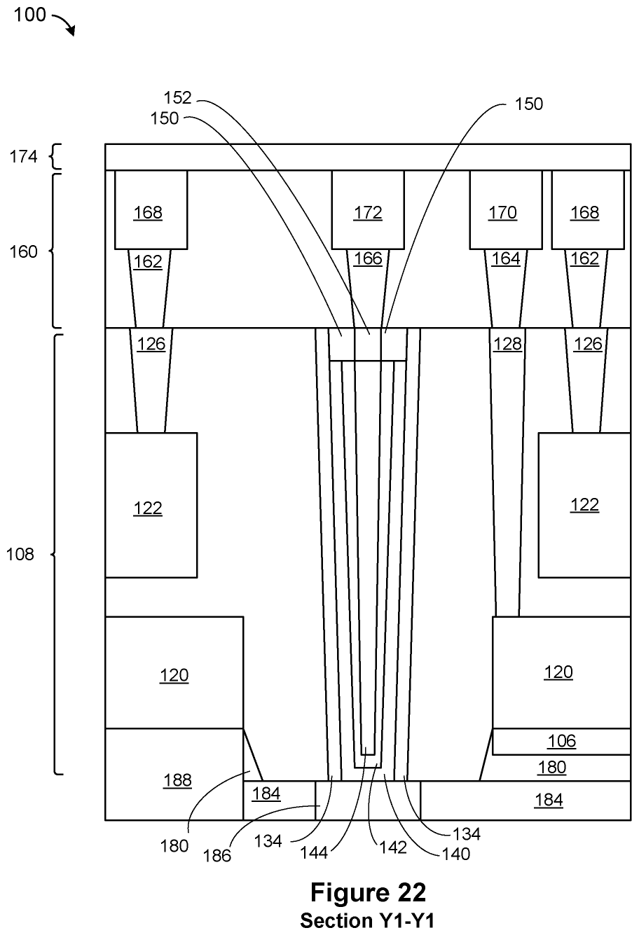

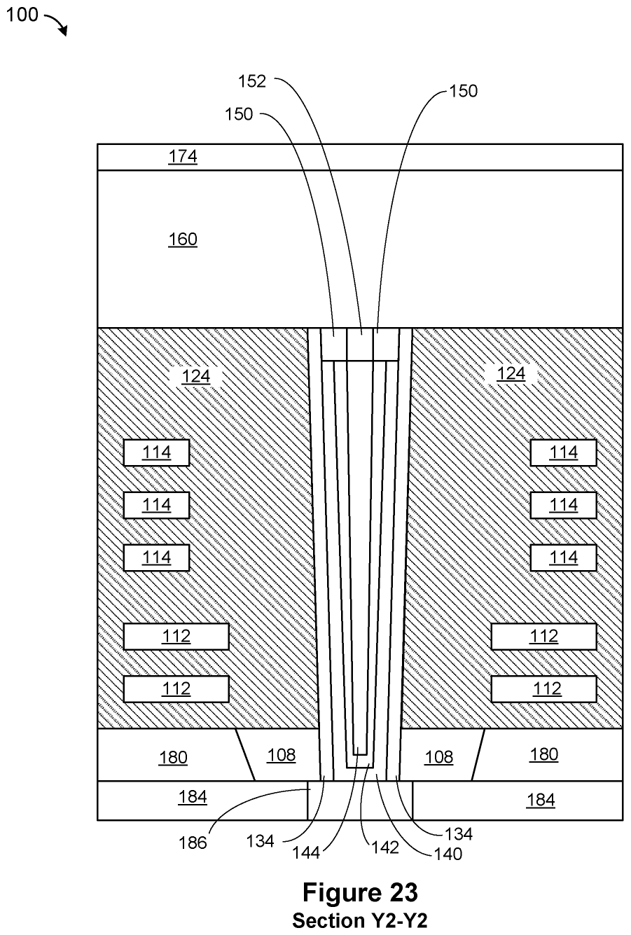

Referring now to FIGS. 22 and 23, the structure 100 is shown according to an exemplary embodiment. FIG. 22 is a cross-sectional view of the structure 100 along section line Y1-Y1. FIG. 23 is a cross-sectional view of the structure 100 along section line Y2-Y2. FIGS. 22 and 23 are parallel to each other. An inter-layer dielectric (hereinafter “ILD”) 180 may be formed. A contact 182 and a contact 184 may be formed.

The ILD 180 may be formed as described for the ILD 108 on a lower surface of the structure 100. The ILD 180 may be formed on the lower horizontal surface of the ILD 108, on a lower horizontal surface of the ILD 176, on the lower horizontal surface of the source drain 120, on the lower horizontal surface of the liner 134 and on the lower horizontal surface of the outer plate 140.

A planarization process, such as, for example, chemical mechanical polishing (CMP), may be done to remove excess material of the ILD 180 from a lower horizontal surface of the structure 100.

Openings (not shown) may be formed in the ILD 180. The contact 186 may be formed in an opening (not shown) which exposes a lower horizontal surface of the outer plate 144. The contact 188 may be formed in an opening (not shown) which exposes a lower horizontal surface of the source drain 120.

The MIM capacitor has an upper contact or electrode or terminal at an upper surface of the structure 100, through the Mx metal line 172, the via 166, the inner plate metal 152 and the inner plate 140. The MIM capacitor has a lower contact or electrode or terminal at a lower surface of the structure 100, through the contact 186 and the outer plate 144.

The resulting MIM capacitor is placed adjacent to normal function circuitry of the structure 100, specifically next to two double stacked nanosheet FETs. The MIM capacitor is formed in a buried power rail trench.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiment, the practical application or technical improvement over technologies found in the marketplace, or to enable others of ordinary skill in the art to understand the embodiments disclosed herein.

What is claimed is:

1. A semiconductor device comprising:
a metal insulator metal capacitor (MIM capacitor) between adjacent stacked nanosheet field effect transistors.

2. The semiconductor device according to claim 1, wherein the adjacent stacked nanosheet field effect transistors each comprise:
a first nanosheet stack on a substrate comprising alternating layers of a first work function metal and a semiconductor channel material vertically aligned and stacked one on top of another.

3. The semiconductor device according to claim 2, wherein the adjacent stacked nanosheet field effect transistors each comprise:
a second nanosheet stack comprising alternating layers of a second work function metal and the semiconductor channel material vertically aligned and stacked one on top of another, wherein the second nanosheet stack vertically aligned and stacked on top of the first nanosheet stack.

4. The semiconductor device according to claim 3, further comprising:
a top electrode of the MIM capacitor connected to an inner plate of the MIM capacitor, wherein a horizontal upper surface of the top electrode is vertically aligned with an upper horizontal surface of a first contact to a second source drain of the second nanosheet stack.

5. The semiconductor device according to claim 4, further comprising:
a lower electrode of the MIM capacitor connected to an outer plate of the MIM capacitor, wherein a lower horizontal surface of the lower electrode is vertically aligned with a second contact to a first source drain of the first nanosheet stack.

6. The semiconductor device according to claim 1, wherein
a height of the MIM capacitor is greater than a height of the adjacent stacked nanosheet field effect transistors.

7. The semiconductor device according to claim 2, further comprising:
a liner separating the MIM capacitor from the first work function metal.

8. A semiconductor device comprising:
a metal insulator metal capacitor (MIM capacitor) between adjacent stacked nanosheet field effect transistors,
wherein the adjacent stacked nanosheet field effect transistors each comprise:
a first nanosheet stack on a substrate comprising alternating layers of a first work function metal and a semiconductor channel material vertically aligned and stacked one on top of another; and
a second nanosheet stack comprising alternating layers of a second work function metal and the semiconductor channel material vertically aligned and stacked one on top of another, wherein the second nanosheet stack vertically aligned and stacked on top of the first nanosheet stack.

9. The semiconductor device according to claim 8, further comprising:
a top electrode of the MIM capacitor connected to an inner plate of the MIM capacitor, wherein a horizontal upper surface of the top electrode is vertically aligned with an upper horizontal surface of a contact to a second source drain of the second nanosheet stack.

10. The semiconductor device according to claim 9, further comprising:
a lower electrode of the MIM capacitor connected to an outer plate of the MIM capacitor, wherein a lower horizontal surface of the lower electrode is vertically aligned with a contact to a first source drain of the first nanosheet device.

11. The semiconductor device according to claim 8, wherein
a height of the MIM capacitor is greater than a height of the adjacent stacked nanosheet field effect transistors.

12. The semiconductor device according to claim 8, further comprising:
a liner separating the MIM capacitor from the first work function metal.

13. A method of forming a semiconductor device comprising:
forming adjacent stacked nanosheet field effect transistors, wherein each adjacent stacked nanosheet field effect transistor comprises:
a first nanosheet stack on a substrate comprising alternating layers of a first work function metal and a semiconductor channel material vertically aligned and stacked one on top of another; and
a second nanosheet stack comprising alternating layers of a second work function metal and the semiconductor channel material vertically aligned and stacked one on top of another, the second nanosheet stack vertically aligned and stacked on top of the first nanosheet stack; and
forming a metal insulator metal capacitor (MIM capacitor) between adjacent stacked nanosheet field effect transistors.

14. The method according to claim 13, further comprising:
forming a top electrode of the MIM capacitor connected to an inner plate of the MIM capacitor, wherein a horizontal upper surface of the top electrode is vertically aligned with an upper horizontal surface of a contact to a second source drain of the second nanosheet stack.

15. The method according to claim 13, further comprising:
forming a lower electrode of the MIM capacitor connected to an outer plate of the MIM capacitor, wherein a lower horizontal surface of the lower electrode is vertically aligned with a contact to a first source drain of the first nanosheet stack.

16. The method according to claim 13, wherein
a height of the MIM capacitor is greater than a height of the adjacent stacked nanosheet field effect transistors.

17. The method according to claim 14, further comprising:
forming a liner separating the MIM capacitor from the first work function metal.

18. The method according to claim 13, wherein
an upper horizontal surface of the MIM capacitor is above an upper horizontal surface of a second source drain of the second nanosheet stack.

19. The method according to claim 13, wherein
a lower horizontal surface of the MIM capacitor is below a lower horizontal surface of a first source drain of the first nanosheet stack.
